(19) United States
(12) Patent Application Publication
(10) Pub. No.: US 2026/0047361 A1
(43) Pub. Date: Feb. 12, 2026

(54) METHOD AND APPARATUS FOR ATOMIC LAYER DEPOSITION USING MULTIPLE CHAMBERS

(71) Applicant: National Tsing Hua University, Hsinchu City (TW)

(72) Inventors: Po-Wen Chiu, Hsinchu City (TW); Jui-Kang Yen, Zhubei City (TW)

(73) Assignee: National Tsing Hua University, Hsinchu City (TW)

(21) Appl. No.: 18/798,955

(22) Filed: Aug. 9, 2024

(51) Int. Cl. H01L 21/02; C23C 16/34; C23C 16/455; C23C 16/48; C23C 16/52; H01L 21/67; H01L 21/677; H01L 21/687

(52) U.S. Cl. CPC H01L 21/0228; C23C 16/345; C23C 16/45534; C23C 16/45565; C23C 16/482; C23C 16/52; H01L 21/0217; H01L 21/67167; H01L 21/67739; H01L 21/68707

(57) ABSTRACT

A method for implementing a thin film deposition process includes: transporting a substrate into a first chamber; feeding a precursor into the first chamber, the precursor being adsorbed on a top surface of the substrate; supplying radiant energy to at least a part of the top surface of the substrate to facilitate reaction between the precursor and the top surface of the substrate; transporting the substrate with the top surface being precursor-adsorbed into a second chamber that is separated from the first chamber and that is spatially isolated from the first chamber; feeding a reactant into the second chamber, wherein reaction between the reactant and the precursor results in a thin film forming on the top surface.

### FIELD

The disclosure relates to a method and an apparatus for implementing atomic layer deposition, and more particularly to a method and an apparatus for implementing atomic layer deposition using multiple chambers.

### BACKGROUND

The technique of thin-film deposition has become a very important process in the field of fabricating semiconductor devices. In various processes used for implementing thin-film deposition, atomic layer deposition (ALD) technique is gaining importance since ALD is capable of producing very thin films with relatively higher conformity and precision, and therefore is favorable in more advanced fabricating processes and is applicable in many relevant fields such as multiple patterning, 3-dimensional NAND flash memory, fin field-effect transistors (FinFETs), gate-all-around FETs (GAAFETs), etc. Generally, the ALD process may be advantageous in improving a conformity and a thermal budget associated with the process.

In general, an ALD process includes four main steps: (1) introducing a chemical gas (known as a precursor) in a chamber that contains a substrate, such that the precursor is adsorbed on a surface of the substrate; (2) introducing an inert gas in the chamber to evacuate the precursor from the chamber; (3) introducing a reactant gas in the chamber so that the reactant gas reacts with the precursor on the surface of the substrate, thus forming a thin film on the surface; and (4) introducing the inert gas in the chamber to evacuate the precursor from the chamber.

### SUMMARY

Therefore, an object of the disclosure is to provide a method for implementing an atomic layer deposition process that can alleviate at least one of the drawbacks of the prior art.

According to one aspect of the disclosure, a method for implementing a thin film deposition process is provided. The method includes:
a) transporting a substrate into a first chamber;
b) feeding a precursor into the first chamber, the precursor being adsorbed on a top surface of the substrate;
c) transporting the substrate with the top surface being precursor-adsorbed into a second chamber that is separated from the first chamber;
d) feeding a reactant into the second chamber;
e) supplying energy to at least a part of the top surface of the substrate to facilitate reaction between the reactant and the precursor, thereby forming a thin film on the top surface;
f) determining whether the thin film deposition process has reached a complete condition; and
in a case where the thin film deposition process has not reached the complete condition, repeating steps a) to f).

Another object of the disclosure is to provide a system that is configured to implement the above-mentioned method.

According to one embodiment of the disclosure, a system for implementing a thin film deposition process is provided. The system includes:
a first chamber that is for holding a substrate, wherein when a precursor is introduced into the first chamber, the precursor is adsorbed on a top surface of the substrate;
a first energy source that is contained in the first chamber and that, when activated, is configured to supply energy to at least a part of the top surface of the substrate;
a second chamber that is separated from the first chamber;
a robotic arm that is configured to transport the substrate from the first chamber to the second chamber;
a second energy source that is contained in the second chamber and that, when activated after a reactant is introduced into the second chamber, is configured to supply energy to at least a part of the top surface of the substrate, the energy thus supplied facilitating reaction between the reactant and the precursor on the top surface, forming a thin film on the top surface; and
a controlling unit that determines whether the thin film deposition process has reached a complete condition; and in a case where the thin film deposition process has not reached the complete condition, controlling the robotic arm to transport the substrate from the second chamber to the first chamber.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram of a system for implementing an atomic layer deposition (ALD) process according to one embodiment of the disclosure.

FIG. 2 is a flow chart illustrating steps of a method for implementing an ALD process according to one embodiment of the disclosure.

FIG. 3 illustrates changes to a substrate in different stages of an ALD process during the method of FIG. 2 according to one embodiment of the disclosure.

FIG. 4 illustrates an exemplary implementation of the system according to one embodiment of the disclosure.

FIG. 5 is a diagram illustrating the operations of different elements of the system during one cycle of an exemplary ALD process according to one embodiment of the disclosure.

FIG. 6 is a diagram illustrating the operations of different elements during one cycle of an exemplary ALD process according to one embodiment of the disclosure.

FIG. 7 is a diagram illustrating the operations of different elements during one cycle of an exemplary ALD process according to one embodiment of the disclosure.

FIG. 8 is a diagram illustrating the operations of different elements during one cycle of an exemplary ALD process according to one embodiment of the disclosure.

FIG. 9 illustrates a relationship of the energy carried by the UV light with different wavelengths.

FIGS. 10 and 11 illustrate the spectrum characteristics of a number of ultraviolet lamps.

FIG. 12 is a schematic diagram illustrating an alternative setup for the system according to one embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

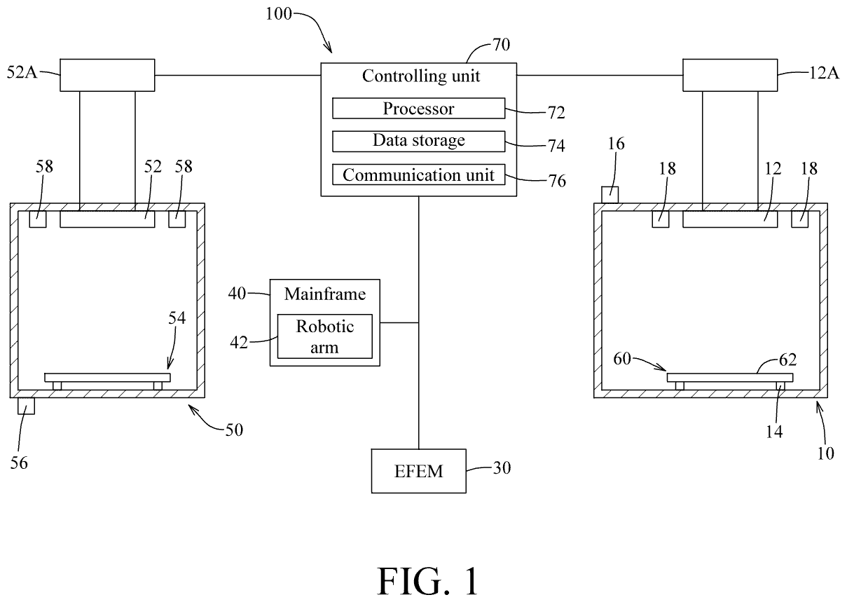

FIG. 1 is a schematic diagram of a system 100 for implementing a thin film deposition process according to one embodiment of the disclosure. In some embodiments, the thin film deposition process may be, for example, an atomic layer deposition (ALD) process. In some embodiments, the system 100 includes a first chamber 10, an equipment front end module (EFEM) 30, a mainframe 40, a second chamber 50, and a controller unit 70.

The first chamber 10 may be embodied using a vacuum chamber that is commercially available, and accommodates a first shower head 12, an object holder 14, a vacuum valve 16, and a first energy source 18.

In use, the object holder 14 is configured to hold a substrate 60 inside the first chamber 10. The substrate 60 may be embodied using a wafer or other suitable objects, and has a top surface 62. In some embodiments, the substrate 60 includes, for example but not limited to, a semiconductor material, a dielectric material, a conductor material, an insulating material, or any combination thereof.

The first shower head 12 may be embodied using a board with a plurality of nozzles or through holes formed thereon, and is connected to a supply reservoir 12A that contains a precursor. The supply reservoir 12A may be controlled to feed the precursor into the first chamber 10 via the first shower head 12. The precursor may be in the form of gas, such as Bis(tertiary-butylamino)silane (BTBAS) or other suitable chemical gas. Generally, in the ALD process, the precursor and the substrate 60 are designed such that the precursor is able to be adsorbed on the top surface 62 of the substrate 60. In some embodiments, the precursor may be a gas, a liquid or a solid at room temperature, which ranges from 5 degrees Celsius to 150 degrees Celsius. In some embodiments, a portion of the precursor is adsorbed on the top surface 62 of the substrate 60 through chemical adsorption; for example, a strong bond is formed between the solid top surface 62 and gas-phase molecules derived from the precursor. Moreover, a portion of the precursor is adsorbed on the top surface 62 of the substrate 60 through physical adsorption, for example, through the van der Waals force.

In some embodiments, the precursor may include one or more silicon compounds such as, for example, a silane, a halosilane or an aminosilane. A silane contains hydrogen and/or carbon groups, but does not contain a halogen. Examples of silanes are silane (SiH₄), disilane (Si₂H₆), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Specific chlorosilanes are tetrachlorosilane (SiCl ₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri-and tetra-aminosilane (H₃Si(NH₂)₄, H₂SKNH₂)₂, HSi(NH₂)₃ and Si(NH₂)₄, respectively), as well as substituted mono-, di-, tri-and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)2, (Si(CH₃)₂NH)₃ and the like. A further example of an aminosilane is trisilylamine (N(SiH₃)).

The vacuum valve 16 is controlled to extract air from the first chamber 10. It is noted that the vacuum valve 16 may be embodied using equipment that is commercially available, and details regarding the specific operations associated with the vacuum valve 16 are omitted herein for the sake of brevity. In some embodiments, hydrogen is introduced into the first chamber 10 as a purge gas to evacuate the precursor not adsorbed on the substrate 60 from the first chamber 10.

The first energy source 18, when activated, is configured to supply energy to at least a part of the top surface 62 of the substrate 60 held by the object holder 14. In different implementations, the first energy source 18 may be configured to supply one or more of an ultraviolet (UV) ray, thermal radiation, a laser ray, or other suitable energy sources. In one example, the first energy source 18 may include a UV lamp that is activated at all times, and a shutter that is disposed between the UV lamp and the first chamber 10. The shutter can be configured to close (such that the UV ray emitted by the UV lamp does not propagate into the chamber 10) and open (such that the UV ray strikes the substrate 60).

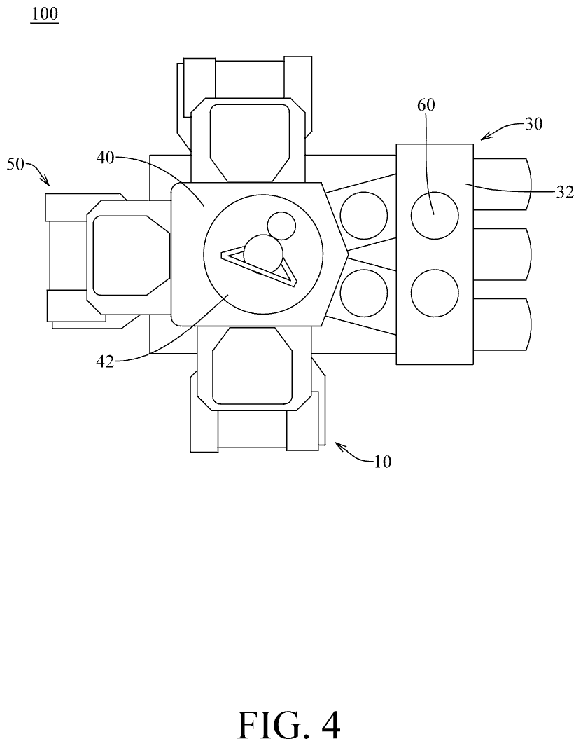

The EFEM 30 and the mainframe 40 are configured to transport a substrate 60 into one of the first chamber 10 and the second chamber 50. Specifically, FIG. 4 illustrates an exemplary implementation of the system 100 according to one embodiment of the disclosure. In the embodiment of FIG. 4, the EFEM 30 includes a housing 32 that is capable of storing a number of substrates 60. The mainframe 40 is spatial communication with to the housing 32, and includes a robotic arm 42 that can be controlled to transport the substrates 60 among the housing 32, the first chamber 10, and the second chamber 50. It is noted that the EFEM 30 and the mainframe 40 may be embodied using equipment that is commercially available, and details regarding the specific operations associated with the EFEM 30 and the robotic arm 42 are omitted herein for the sake of brevity.

The second chamber 50 may be embodied using a chamber that is similar to the first chamber 10, and accommodates a shower head 52, an object holder 54, a vacuum valve 56, and an energy source 58. In embodiments, the second chamber 50 is spatially separated from the first chamber 10. That is to say, when the substrate 60 is placed in one of the first chamber 10 and the second chamber 50, the one of the first chamber 10 and the second chamber 50 is not in spatial communication with the other one of the first chamber 10 and the second chamber 50. Each of the first chamber 10 and the second chamber 50 may be embodied using any commercially available model.

The shower head 52 may be similar to the first shower head 12, and is connected to a reservoir 52A that contains a reactant. The reactant may be oxygan gas (O₂), ozone (O₃), water (H₂O), ammonia (NH₃) or other suitable chemical compounds, substances or plasmas.

In some embodiments, the reactant may include a nitrogen-containing reactant such as, for example, ammonia, hydrazine, amines (amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

The supply reservoir 52A may be controlled to feed the reactant into the second chamber 50 via the shower head 52. The reactant is typically selected to be able to react with the precursor, so as to yield a product. Specifically, when the reactant reacts with the precursor adsorbed on the top surface 62 of a substrate 60, the product is formed on the top surface 62, thereby achieving the effect of forming a thin film on the top surface 62.

The object holder 54 may be similar to the object holder 14, and is configured to hold a substrate 60 inside the second chamber 50.

The vacuum valve 56 is configured to extract air from the second chamber 50.

The energy source 58, when activated, is configured to supply energy onto at least a part of the top surface 62 held by the object holder 54. In different implementations, the energy source 58 may be configured to supply one or more of a UV ray, thermal radiation, a laser ray, or other suitable energy sources.

The controlling unit 70 may be embodied using a server, an industrial computer, a personal computer, a laptop or other suitable devices. The controlling unit 70 is connected to the supply reservoir 12A, the vacuum valve 16, the first energy source 18, the EFEM 30, the robotic arm 42, the supply reservoir 52A, the vacuum valve 56 and the energy source 58.

The controlling unit 70 includes a processor 72, a data storage 74 and a communication unit 76.

The processor 72 may be embodied using a central processing unit (CPU), a microprocessor, a microcontroller, a single core processor, a multi-core processor, a dual-core mobile processor, a microprocessor, a microcontroller, a digital signal processor (DSP), a field-programmable gate array (FPGA), an application specific integrated circuit (ASIC), and/or a radio-frequency integrated circuit (RFIC), etc.

The data storage 74 is connected to the processor 72, and may be embodied using, for example, random access memory (RAM), read only memory (ROM), programmable ROM (PROM), firmware, flash memory, etc. In this embodiment, the data storage 74 stores a software application therein. The software application includes instructions that, when executed by the processor 72, cause the processor 72 to implement the operations as described below.

The communication unit 76 is connected to the processor 72, and may include one or more of a radio-frequency integrated circuit (RFIC), a short-range wireless communication module supporting a short-range wireless communication network using a wireless technology of Bluetooth® and/or Wi-Fi, etc., and a mobile communication module supporting telecommunication using Long-Term Evolution (LTE), the third generation (3G), the fourth generation (4G) or fifth generation (5G) of wireless mobile telecommunications technology, or the like. The communication unit 76 enables the controlling unit 70 to communicate with each of the supply reservoir 12A, the vacuum valve 16, the first energy source 18, the EFEM 30, the robotic arm 42, the supply reservoir 52A, the vacuum valve 56 and the energy source 58 via a wired connection and/or a wireless network (e.g., a local area network (LAN), the Internet, etc.).

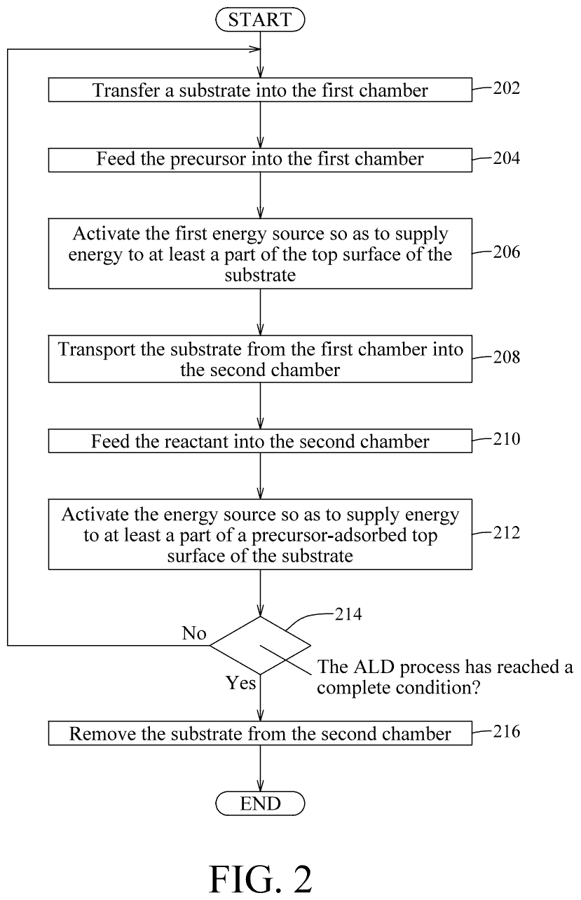

FIG. 2 is a flow chart illustrating steps of a method for implementing an ALD process according to one embodiment of the disclosure. In some embodiments, the method 200 is implemented using the system 100 as shown in FIG. 1. In use, the controlling unit 70 is configured to control various components of the system 100 to perform the operation as described below.

In use, it is desired to implement an ALD process to form a thin film on the top surface 62 of a substrate 60. In conventional ALD processes, only one chamber is employed, the precursor is first introduced into the chamber, and after the precursor is adsorbed on the surface, the vacuum valve is activated to extract the gas from the chamber, thereby evacuating portions of the precursor not adsorbed on the surface, and then, the reactant is introduced into the chamber to form the thin film. In this manner, the precursor may be incompletely evacuated, and some of the precursor particles may be left on the shower head and/or an inner surface of the chamber. As a result, the precursor and the reactant may react on the shower head and/or the inner surface of the chamber, forming small layers thereon. After the chamber is used for implementing the ALD process numerous times, those small layers may then detach from the shower head and/or the inner surface of the chamber and fall onto a substrate is currently placed in the chamber, which may contaminate the substrate and negatively affecting a product yield of the associated semiconductor device. In order to prevent such an occurrence, the chamber and the shower head would need to be cleaned after a certain number of ALD processes have been implemented. Since cleaning the chamber and the shower head is troublesome, it may be beneficial to eliminate the possibility of the precursor and the reactor gas reacting on the shower head and/or the inner surface of the chamber.

Therefore, the system 100 as shown in FIG. 1 is designed to include two different chambers, such that the potential scenario of the reactant being introduced in the chamber with the precursor still in the chamber can be eliminated.

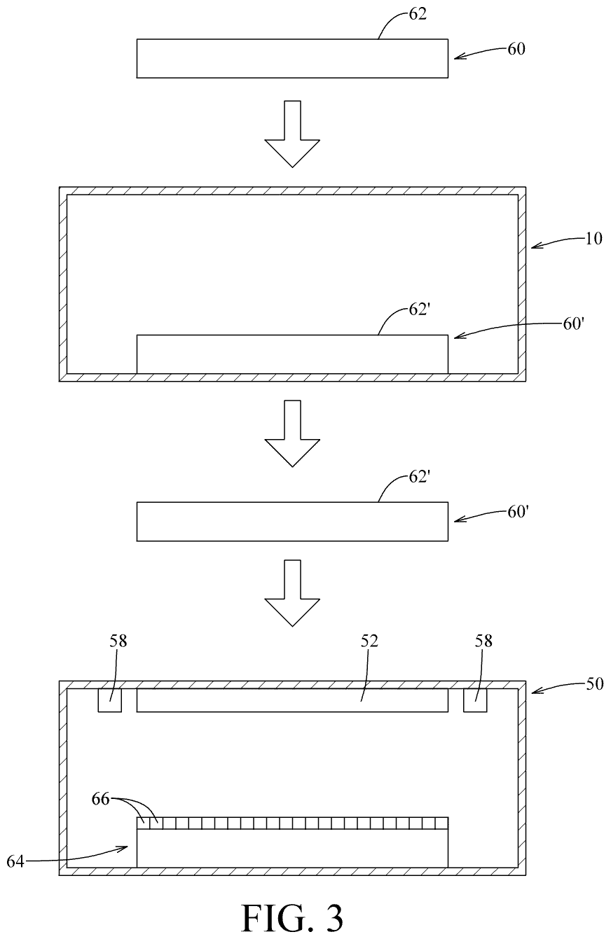

FIG. 3 illustrates changes to a substrate 60 in different stages of an ALD process during the method of FIG. 2 according to one embodiment of the disclosure.

In step 202, at the start of the ALD process, the controlling unit 70 controls the robotic arm 42 of the mainframe 40 to transport one of the substrates 60 stored in the housing 32 of the EFEM 30 into the first chamber 10, and the substrate 60 is then held by the object holder 14.

Then, in step 204, the controlling unit 70 controls the supply reservoir 12A to feed the precursor into the first chamber 10 via the first shower head 12.

Then, in step 206, the controlling unit 70 activates the first energy source 18 so as to supply energy to at least a part of the top surface 62 of the substrate 60 held by the object holder 14. As such, the energy thus supplied facilitates adsorption of the precursor on the top surface 62 of the substrate 60. For ease of explanation, the substrate referred to in step 202 is also called the “first substrate” herein, and the substrate 60 with the adsorption of the precursor on the top surface 62 is also called the “second substrate” 60′ having a precursor-adsorbed top surface 62′.

It is noted that in various embodiments, the first energy source 18 may be configured to supply a radiant energy. For example, in one embodiment, the first energy source 18 is configured to supply the radiant energy by emitting an ultraviolet (UV) light with a wavelength of 10 nanometers (nm) to 400 nm. In some embodiments, the wavelength of the UV light is longer than about 100 nm and is shorter than about 380 nm.

In some embodiments, the wavelength of the UV light is shorter than about 300 nm. In some embodiments, the wavelength of the UV light is shorter than about 250 nm.

In different embodiments, the first energy source 18 is a UV light source, and may be embodied using various lamps. For example, the first energy source 18 may be embodied using one of a mercury arc lamp, an amalgam mercury lamp, a laser, an excimer lamp, a light-emitting diode, a xenon-containing lamp, a krypton-containing lamp, a mercury vapor lamp, a metal-halide lamp, a deuterium (D2) lamp, etc, and combinations thereof.

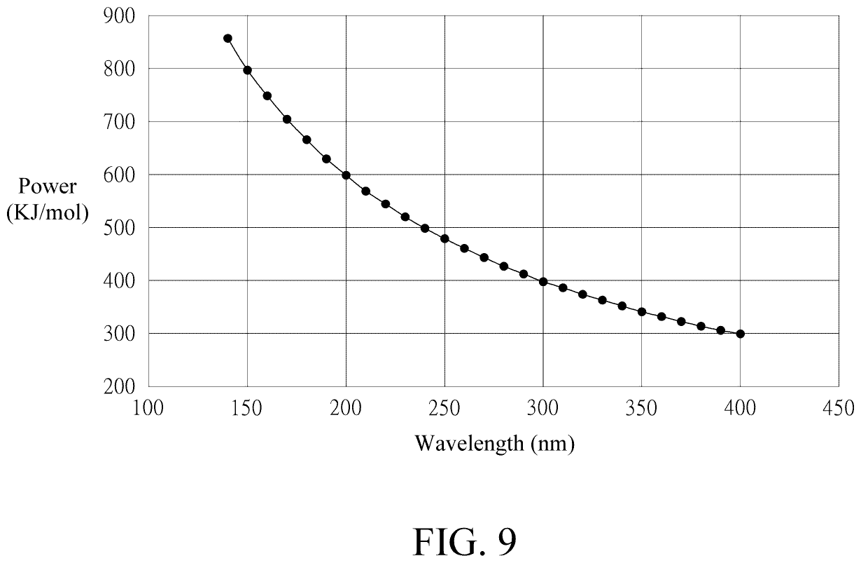

FIG. 9 illustrates a relationship of the energy carried by the UV light with different wavelengths. Generally, UV light with a shorter wavelength carries higher energy. In order to facilitate the reactions between the precursor and the molecules on the surface of the substrate 60, the UV light with a certain amount of energy may be supplied to break off certain chemical bonds. Based on different cases of the precursor used, UV light with specific wavelengths may be provided

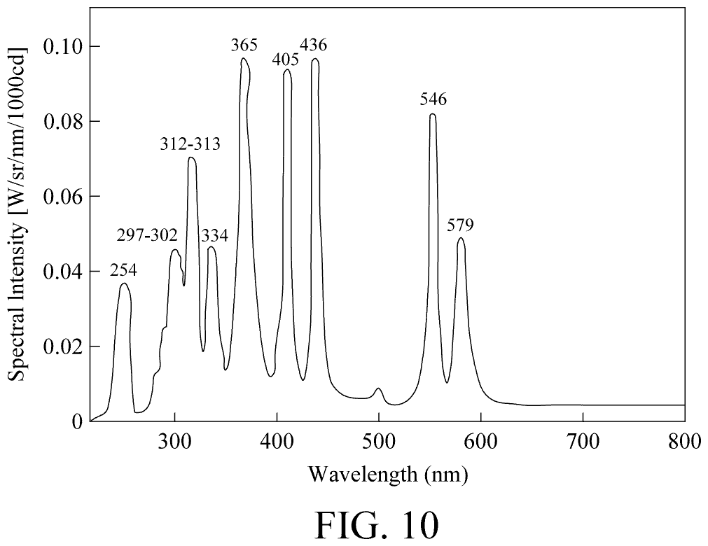

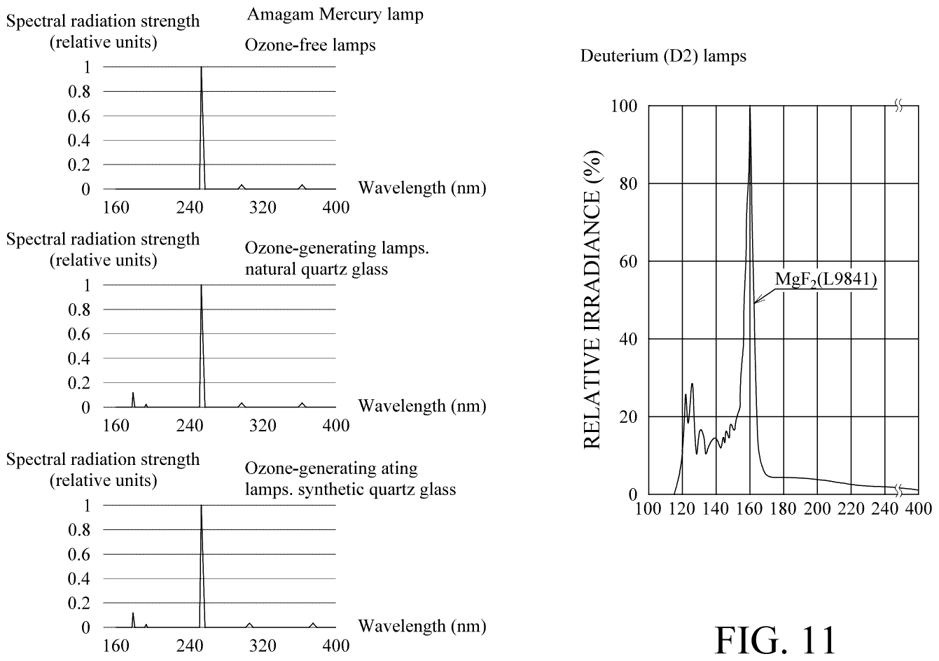

FIGS. 10 and 11 illustrate the spectrum characteristics of the UV lamps as mentioned above. It is noted that each of the lamps may provide UV lights with different spectral intensity, and therefore different lamps may be employed for different ALD processes. Based on FIG. 10, it is evident that the intensity of the UV light provided by a mercury arc lamp has a local maximum when the wavelength of the UV light is about 300 nm. Based on FIG. 11, it is evident that the intensities of the UV lights provided by amalgam mercury lamps have global maxima when the wavelengths of the UV lights are about 250 nm.

In other embodiments, the first energy source 18 is configured to supply the radiant energy by emitting a laser beam, or providing heat, etc.

Then, in step 208, the controlling unit 70 controls the robotic arm 42 to transport the second substrate 60′ from the first chamber 10 into the second chamber 50, and the second substrate 60′ is then held by the object holder 54. After the second substrate 60′ is removed from the first chamber 10, the controlling unit 70 may control the vacuum valve 16 to evacuate the precursor from the first chamber 10.

Then, in step 210, the controlling unit 70 controls the supply reservoir 52A to feed the reactant into the second chamber 50 via the shower head 52.

Then, in step 212, the controlling unit 70 activates the energy source 58 so as to supply energy to at least a part of the precursor-adsorbed top surface 62′ of the second substrate 60′ held by the object holder 54. As such, the energy thus supplied facilitates reaction between the reactant and the precursor on the precursor-adsorbed top surface 62′, thereby forming a thin film 66 on the precursor-adsorbed top surface 62′ so as to create a third substrate 64.

It is noted that in various embodiments, the energy source 58 is similar to the energy source 18 and may be configured to supply a radiant energy. For example, in one embodiment, the energy source 58 is configured to supply the radiant energy by emitting an ultraviolet (UV) light with a wavelength of 10 nm to 400 nm. In some embodiments, the wavelength of the UV light is longer than about 100 nm and is shorter than about 380 nm. In other embodiments, the energy source 58 is configured to supply the radiant energy by emitting a laser beam, or providing heat, etc. In some embodiments, the precursor adsorbed on the second substrate 60′ undergoes the pyrolysis process under irradiation of the UV light, which facilitates reaction between the precursor and the reactant and formation of the thin film 66.

It is noted that in some embodiments, the precursor and the reactant may be selected in such a manner that the reaction between the precursor and the reactant does not occur without the energy being supplied. That is to say, the formation of the thin film 66 may be controlled by selectively supplying energy on parts of the precursor-adsorbed top surface 62′.

Then, in step 214, the controlling unit 70 determines whether the ALD process has reached a complete condition. In the case where the controlling unit 70 determines that the ALD process has reached the complete condition, the flow proceeds to step 216, in which the controlling unit 70 controls the robotic arm 42 to remove the third substrate 64 from the second chamber 50 (e.g., to transport the third substrate 64 back to the EFEM 30), and the method is completed.

On the other hand, when it is determined that the ALD process has not reached the complete condition, the flow goes back to step 202, in which the controlling unit 70 controls the robotic arm 42 to transport the third substrate 64 to the first chamber 10. Then, the operations of steps 202 to 212 may be repeated again to form another thin film, with the third substrate 64 serving as the first substrate in steps 202 to 206.

In some embodiments, the determination as to whether the ALD process has reached the complete condition may be done by determining whether a thickness of the thin film 66 of the third substrate 64 is larger than a predetermined target thickness (e.g., 1 nm or 50 nm). That is, the complete condition may be associated with the thickness of the thin film 66, and when the thickness of the thin film 66 has not yet reached the predetermined target thickness, the operations of steps 202 to 212 will be repeated until the thickness of the thin film 66 has reached the predetermined target thickness.

In some embodiments, the determination as to whether the ALD process has reached the complete condition may be done by determining whether a number of repetitions of the operations of steps 202 to 212 (i.e., a number of cycles implemented) has reached a predetermined target number (e.g., any number selected from 50 to 1000). That is, the complete condition may be associated with the number of repetitions of the operations of steps 202 to 212, and when the number of repetitions of the operations of steps 202 to 212 has not yet reached the predetermined target number, the operations of steps 202 to 212 (i.e., another cycle) will be implemented until the number of repetitions of the operations of steps 202 to 212 has reached the predetermined target number.

In brief, embodiments of the disclosure provide a method and a system for implementing an ALD process. In the method, a substrate is transported into a first chamber of the system, and then a precursor is introduced into the first chamber to be adsorbed on a surface of the substrate to form the raw substrate into a second substrate. Afterward, the second substrate is transported to a second chamber of the system, and then a reactant is introduced into the second chamber to react with the precursor on a part of a precursor-adsorbed surface of the second substrate, thereby forming a thin film as a result. In addition, energy sources are controlled to supply energy to at least a part of the surface of the substrate in the first chamber and at least a part of the precursor-adsorbed surface of the second substrate, in order to facilitate the adsorption of the precursor on the surface of the substrate, and facilitate the reaction between the reactant and the precursor on the part of the precursor-adsorbed surface of the second substrate.

In this manner, the reaction between the reactant and the precursor occurs in the second chamber. Since the precursor is introduced into the first chamber instead of the second chamber where the reactant is introduced into, a scenario where the precursor is left on an inner surface of the second chamber and/or a shower head contained in the second chamber is eliminated. As such, the potential scenario where the reactant reacts with the precursor on the inner surface of the second chamber and/or the shower head contained in the second chamber, thereby forming small fragments of thin films thereon, is also eliminated.

It is noted that in some embodiments, the operations of steps 204 and 206 may be implemented simultaneously. That is, as the precursor is being introduced into the first chamber 10, the first energy source 18 may be activated to supply energy to the substrate 60. Similarly, the operations of steps 210 and 212 may be implemented simultaneously. That is, as the reactant is being introduced into the second chamber 50, the energy source 58 may be activated to supply energy to the second substrate 60′.

It is noted that while in the embodiment of FIG. 2, the operations of supplying energy are implemented in both steps 206 and 212, in other embodiments, one of steps 206 and 212 may be omitted. For example, in one embodiment, after the controlling unit 70 controls the supply reservoir 12A to feed the precursor into the first chamber 10 via the first shower head 12 in step 204, the flow may directly proceed to step 208.

Alternatively, in another embodiment, after the operation of supplying energy is implemented in step 206, the operation of transporting the to-be-deposited substrate from the first chamber to the second chamber in step 208, and the operation of feeding the reactant into the second chamber in step 210, the flow may directly proceed to step 214. In such a case, while the reactant may land on the precursor-adsorbed top surface 62′, no reaction would occur in the second chamber 50. As such, it would be determined in step 214 that the ALD process has not reached the complete condition (since the thin film has not yet been formed), the flow goes back to step 202, and operations of steps 202 to 210 may be repeated again to form a thin film. Specifically, in this case, the second substrate 60′ with the reactant thereon is transported back to the first chamber 10, and then in step 206, when the controlling unit 70 activates the first energy source so as to supply energy to at least a part of the precursor-adsorbed top surface 62′, the energy would facilitate reaction between the reactant and the precursor on the precursor-adsorbed top surface 62′, thereby forming a thin film 66 on the precursor-adsorbed top surface 62′ in the first chamber 10. For different precursors and/or different reactants, different processes may be employed.

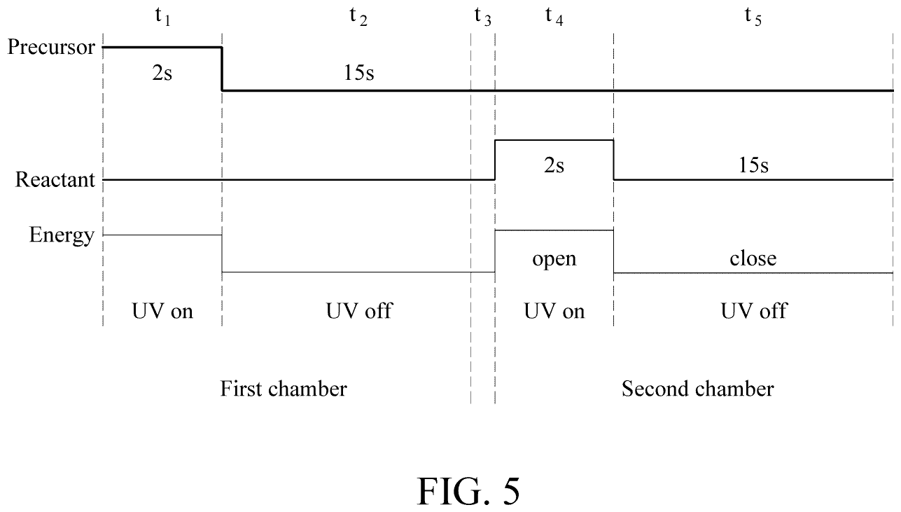

FIG. 5 is a diagram illustrating the operations of different elements of the system during one cycle of an exemplary ALD process according to one embodiment of the disclosure. In the example of FIG. 5, as the precursor is being introduced into the first chamber 10 in the time interval t₁, the first energy source 18 is activated to supply energy to the substrate 60. Afterward, at the start of the time interval t₂, the controller unit 70 stops introducing the precursor into the first chamber 10, and the first energy source 18 is deactivated.

After the second substrate 60′ is transported to the second chamber 50 in the time interval t₃, in the time interval t₄, the reactant is being introduced into the second chamber 50, and the energy source 58 is activated to supply energy to the second substrate 60′. Afterward, at the start of the time interval t ₅, the controller unit 70 stops introducing the reactant into the second chamber 50, and the energy source 58 is deactivated. In other words, energy is supplied to the substrate 60 in the first chamber 10 and the second substrate 60′ in the second chamber 50 during introduction of the precursor and the reactant, respectively.

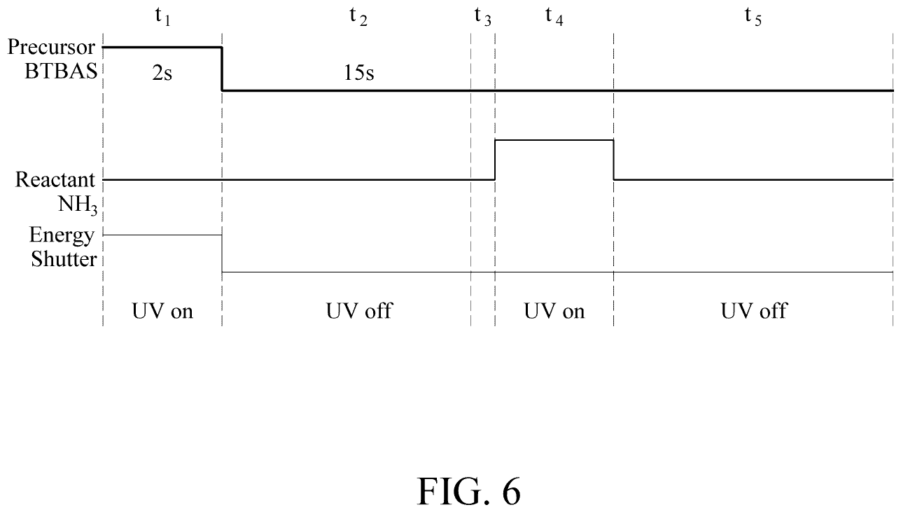

FIG. 6 is a diagram illustrating the operations of different elements of the system during one cycle of an exemplary ALD process according to one embodiment of the disclosure. In the example of FIG. 6, as the precursor is being introduced into the first chamber 10 in the time interval t₁, the first energy source 18 is activated to supply energy to the substrate 60. Afterward, at the start of the time interval t₂, the controller unit 70 stops introducing the precursor into the first chamber 10, and the first energy source 18 is deactivated.

After the second substrate 60′ is transported to the second chamber 50 in the time interval t₃, in the time interval t₄, the reactant is being introduced into the second chamber 50, and the energy source 58 remains deactivated. Afterward, at the start of the time interval t₅, the controller unit 70 stops introducing the reactant into the second chamber 50. In other words, energy is only supplied to the substrate 60 in the first chamber 10 during introduction of the precursor.

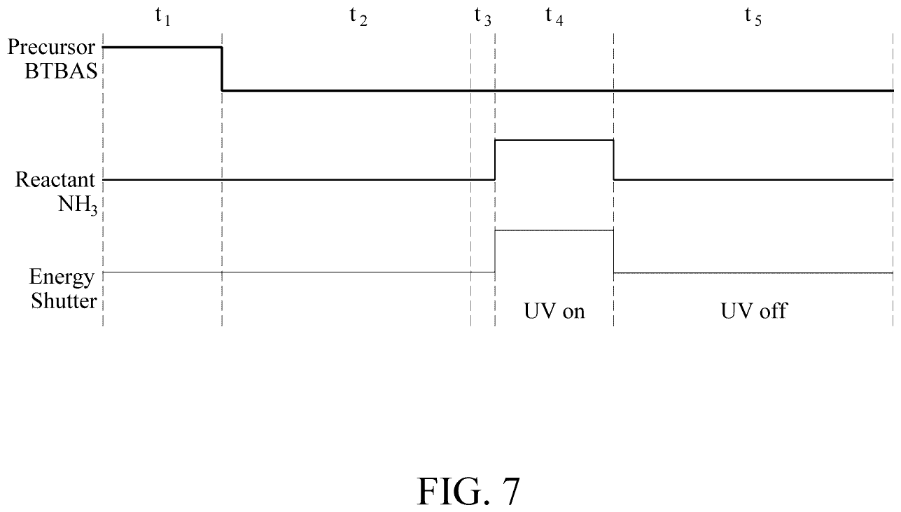

FIG. 7 is a diagram illustrating the operations of different elements during one cycle of an exemplary ALD process according to one embodiment of the disclosure. In the example of FIG. 7, as the precursor is being introduced into the first chamber 10 in the time interval t₁, the first energy source 18 remains deactivated. Afterward, at the start of the time interval t₂, the controller unit 70 stops introducing the precursor into the first chamber 10.

After the second substrate 60′ is transported to the second chamber 50 in the time interval t₃, in the time interval t₄, the reactor gas is being introduced into the second chamber 50, and the energy source 58 is activated to supply energy to the second substrate 60'. Afterward, at the start of the time interval t₅, the controller unit 70 stops introducing the reactor gas into the second chamber 50, and the energy source 58 is deactivated. In other words, energy is only supplied to the second substrate 60′ in the second chamber 50 during introduction of the reactant.

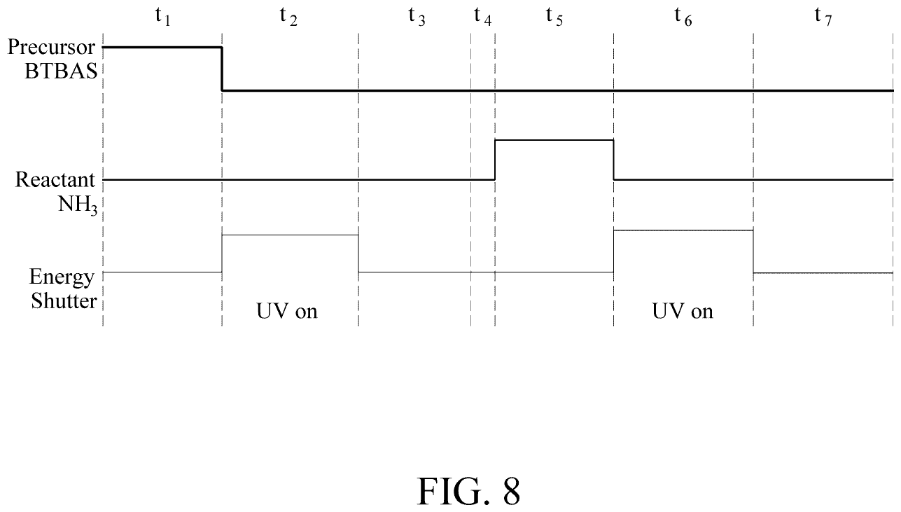

FIG. 8 is a diagram illustrating the operations of different elements during one cycle of an exemplary ALD process according to one embodiment of the disclosure. In the example of FIG. 8, as the precursor is being introduced into the first chamber 10 in the time interval t₁, the first energy source 18 is deactivated. Afterward, at the start of the time interval t₂, the controller unit 70 stops introducing the precursor into the first chamber 10, and the first energy source 18 is activated to supply energy to the substrate 60.

After the time interval t₂ has elapsed, the first energy source 18 is deactivated in the time interval t₃ to stop supplying energy to the substrate 60, and the second substrate 60′ is then transported to the second chamber 50 in the time interval t₄. Then, in the time interval t₅, the reactant is being introduced into the second chamber 50. Next, at the start of the time interval t ₆, the controller unit 70 stops introducing the reactant into the second chamber 50, and the energy source 58 is activated to supply energy to the second substrate 60′. Afterward, at the start of the time interval t₇, the energy source 58 is deactivated. In other words, energy is supplied to both the substrate 60 in the first chamber 10 and the second substrate 60′ in the second chamber 50, with the supply of energy to the substrate 60 in the first chamber 10 and the supply of energy to the second substrate 60′ in the second chamber 50 being after introduction of the precursor and introduction of the reactant, respectively.

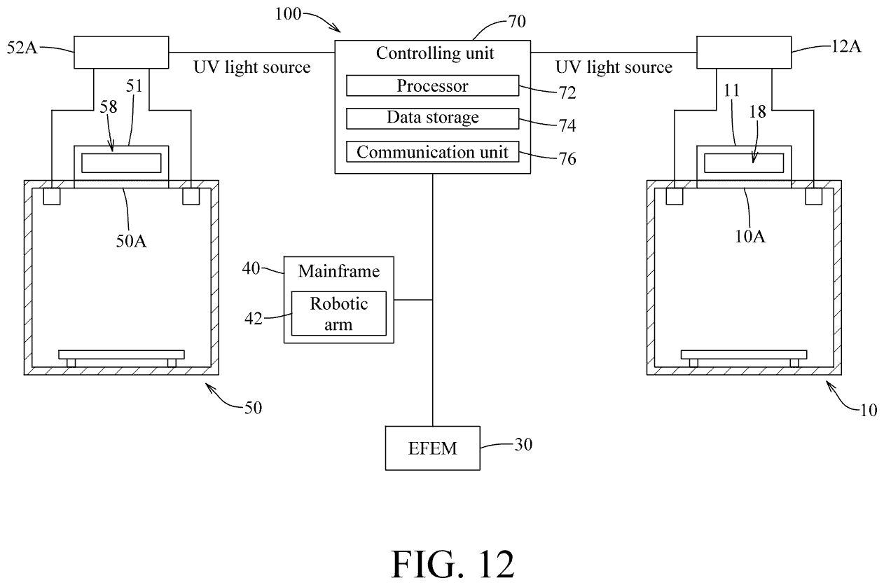

FIG. 12 is a schematic diagram illustrating an alternative setup for the system 100 according to one embodiment of the disclosure. In the embodiment of FIG. 12, each of the first chamber 10 and the second chamber 50 may have a top window (labeled as 10A and 50A, respectively) that is formed using a transparent material (e.g., glass), and includes a top compartment (labeled as 11 and 51, respectively) for housing the corresponding energy source 18, 58. The system 100 as shown in FIG. 12 is capable of implementing the method as described above.

One effect of the method is that since small fragments of thin films will not be formed on the inner surface of either the first chamber or the second chamber, the first chamber and the second chamber may need less frequent cleaning as compared to using a single chamber for implementing the ALD process. Additionally, the adverse effect of small fragments of thin films falling onto a substrate may also be eliminated, resulting in an improved product yield.

Moreover, by using the energy source 58 to supply energy onto at least a part of the precursor-adsorbed top surface 62′ of the to-be-deposited substrate 60′, the resulting reactions between the reactant and the precursor may be controlled to occur only on the part of the precursor-adsorbed top surface 62′. In some embodiments, the reactant and the precursor may be selected such that the reactions will not take place without being supplied with the energy. As such, the operations of forming the thin film may be done is a more controlled manner.

In some embodiments, by using the UV light as the source of energy, the resulting ALD process may achieve one or more of the following effects: the ALD process may be implemented at a lower temperature, thereby enabling better thermal budget control; damages related to ion being exposed to energy may be eliminated; formation of the thin film may be more accurately controlled; the thin film may be formed by conducting multiple repetitions to result in enhanced uniformity in the thin film; and the undesired byproducts such as residual bonds may be reduced.

By providing two separate chambers for implementing different steps included in the ALD process, the system as described above and shown in FIG. 1 may also achieve the effects of the method.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for implementing a thin film deposition process, comprising:
a) transporting a substrate into a first chamber;
b) feeding a precursor into the first chamber, the precursor being adsorbed on a top surface of the substrate;
c) supplying radiant energy to at least a part of the top surface of the substrate to facilitate reaction between the precursor and the top surface of the substrate;
d) transporting the substrate with the top surface being precursor-adsorbed into a second chamber that is separated from the first chamber and that is spatially isolated from the first chamber;
e) feeding a reactant into the second chamber, wherein reaction between the reactant and the precursor results in a thin film forming on the top surface;
f) determining whether the thin film deposition process has reached a complete condition; and
in a case where the thin film deposition process has not reached the complete condition, repeating steps a) to f).

2. The method as claimed in claim 1, wherein:
step a) includes controlling one of an equipment front end module (EFEM), a robotic arm and a combination thereof to transport the substrate into the first chamber; and
step c) includes controlling the robotic arm to transport the substrate out of the first chamber and into the second chamber.

3. The method as claimed in claim 1, wherein: step b) includes feeding the precursor into the first chamber via a shower head that is formed with a plurality of nozzles.

4. The methods as claim in claim 1, wherein in step c) the radiant energy is ultraviolet (UV) light with a wavelength shorter than 300 nanometers.

5. The method as claimed in claim 1, wherein: step d) includes feeding the reactant into the second chamber via a shower head that is formed with a plurality of nozzles.

6. The method as claimed in claim 1, wherein step e) further includes supplying radiant energy to at least a part of the top surface of the substrate to facilitate reaction between the reactant and the precursor on the top surface of the substrate.

7. The method as claimed in claim 6, wherein the supplying of radiant energy includes supplying ultraviolet (UV) light with a wavelength shorter than 300 nanometers.

8. The method as claimed in claim 1, wherein step c) includes using a UV lamp to supply radiant energy, the UV lamp being one of a mercury arc lamp, an amalgam mercury lamp, a laser, an excimer lamp, a light-emitting diode, a xenon-containing lamp, a krypton-containing lamp, a mercury vapor lamp, a metal-halide lamp, a deuterium (D2) lamp, and combinations thereof.

9. The method as claimed in claim 1, wherein in step b), the precursor includes a silicon compound.

10. The method as claimed in claim 1, wherein step f) includes determining one of:
whether a thickness of the thin film is larger than a predetermined target thickness; and
whether a number of repetitions of the operations of steps a) to e) has reached a predetermined target number.

11. The method as claimed in claim 1, wherein step e), the reactant includes a nitrogen-containing reactant.

12. A system for implementing a thin film deposition process, comprising:
a first chamber that is for holding a substrate, wherein when a precursor is fed into the first chamber, the precursor is adsorbed on a top surface of the substrate;
a first energy source that is contained in the first chamber and that, when activated, is configured to supply radiant energy to at least a part of the top surface of the substrate to facilitate reaction between the precursor and the top surface of the substrate;
a second chamber that is separated from the first chamber and that is spatially isolated from the first chamber;
a robotic arm that is configured to transport the substrate with the top surface being precursor-adsorbed out of the first chamber into the second chamber, wherein, after a reactant is fed into the second chamber, reaction between the reactant and the precursor results in a thin film forming on the top surface; and
a controlling unit that determines whether the thin film deposition process has reached a complete condition; and in a case where the thin film deposition process has not reached the complete condition, controlling the robotic arm to transport the substrate out of the second chamber into the first chamber.

13. The system as claimed in claim 12, further comprising a shower head that is contained in the first chamber and that is connected to a first supply reservoir which contains the precursor, the first shower head being formed with a plurality of nozzles for feeding the precursor into the first chamber.

14. The system as claimed in claim 12, further comprising a shower head that is contained in the second chamber and that is connected to a second supply reservoir which contains the reactant, the second shower head being formed with a plurality of nozzles for feeding the reactant into the second chamber.

15. The system as claimed in claim 12, wherein the first energy source is configured to supply ultraviolet (UV) light with a wavelength shorter than 300 nanometers.

16. The system as claimed in claim 12, further comprising a second energy source that is contained in the second chamber and that, when activated, is configured to supply radiant energy to at least a part of the top surface of the substrate to facilitate reaction between the reactant and the precursor on the top surface of the substrate.

17. The system as claimed in claim 16, wherein the second energy source is configured to supply ultraviolet (UV) light with a wavelength shorter than 300 nanometers.

18. The system as claimed in claim 12, wherein the first energy source includes a UV lamp, the UV lamp being one of a mercury arc lamp, an amalgam mercury lamp, a laser, an excimer lamp, a light-emitting diode, a xenon-containing lamp, a krypton-containing lamp, a mercury vapor lamp, a metal-halide lamp, a deuterium (D2) lamp, and combinations thereof.

19. The system as claimed in claim 12, wherein the controlling unit is configured to determine whether the thin film process has reached a complete condition by determining one of:
whether a thickness of the thin film is larger than a predetermined target thickness; and
whether a number of cycles of the thin film deposition process implemented by the system has reached a predetermined target number.

20. The system as claimed in claim 12, further comprising an equipment front end module (EFEM) for storing the substrate, wherein the robotic arm is configured to transport the substrate among the EFEM, the first chamber and the second chamber.
